(19) United States
(12) Patent Application Publication
(10) Pub. No.: US 2024/0365629 A1
(43) Pub. Date: Oct. 31, 2024

(54) DISPLAY DEVICE

(71) Applicant: LG Display Co., Ltd., Seoul (KR)

(72) Inventors: ByungYong AHN, Paju-si (KR); WonSo SON, Paju-si (KR); ChangYoon YANG, Paju-si (KR)

(21) Appl. No.: 18/645,066

(22) Filed: Apr. 24, 2024

(30) Foreign Application Priority Data
Apr. 28, 2023 (KR) 10-2023-0055921

(51) Int. Cl. H10K 59/35; H10K 59/121

(52) U.S. Cl. CPC H10K 59/353; H10K 59/1213; H10K 59/351; H10K 59/352

(57) ABSTRACT

Disclosed is a display device comprising a first subpixel including a first light emitting element emitting light of a first color and a first driving transistor driving the first light emitting element, a second subpixel including a second light emitting element emitting light of a second color and a second driving transistor driving the second light emitting element, and a third subpixel including a third driving transistor driving the third light emitting element, and at least two of the first subpixel, the second subpixel, and the third subpixel may have different contact hole area densities.

### CROSS-REFERENCE TO RELATED APPLICATION

This application claims the benefit of the Korean Patent Application No. 10-2023-0055921 filed on Apr. 28, 2023, which is hereby incorporated by reference as if fully set forth herein.

### BACKGROUND

### Technical Field

The present disclosure relates to a display device reducing a low grayscale stain.

### Description of the Related Art

The electroluminescence display device has the advantage of being able to implement it in a free shape as well as high luminance, a low driving voltage, and ultra-thin using a self-luminescent element that emits light through a recombination of electrons and holes.

In the electroluminescent display device, the luminance sensitivity to current fluctuations of the driving transistor may be different for each red, green, and blue subpixel due to characteristic differences such as efficiency of red, green, and blue light emitting devices.

The electroluminescent display device has the same subthreshold swing factor (hereinafter referred to as the S-factor) of the driving transistor for each three-color subpixel, so that the current sensitivity of the driving transistor may be the same regardless of the three-color subpixel.

As a result, the electroluminescent display device has a different luminance distribution according to the same current distribution for each three-color subpixel due to the difference in luminance sensitivity between the three-color subpixels, which may increase the red/green/blue color difference in the low grayscale area, resulting in low grayscale stains.

The descriptions in this section is part of the present disclosure or is technical information acquired by a process of devising the present disclosure, but may not be regarded as the known art disclosed to the general public before the present disclosure is disclosed.

### BRIEF SUMMARY

Various embodiments of the present disclosure provide a display device that, among others, substantially obviate one or more problems due to limitations and disadvantages of the related art.

Various embodiments of the present disclosure provide a display device capable of reducing a low grayscale stain by compensating for a difference in luminance sensitivity by differently applying an S-factor of a driving transistor for each three-color subpixel.

Additional advantages and features of the disclosure will be set forth in part in the description which follows and in part will become apparent to those having ordinary skill in the art upon examination of the following or may be learned from practice of the disclosure. The technical benefits and other advantages of the disclosure may be realized and attained by the structure particularly pointed out in the written description and/or the claims hereof as well as the appended drawings.

To achieve these and other benefits and in accordance with the purpose of the disclosure, as embodied and broadly described herein, there is provided a display device comprising a first subpixel including a first light emitting element emitting light of a first color and a first driving transistor driving the first light emitting element, a second subpixel including a second light emitting element emitting light of a second color and a second driving transistor driving the second light emitting element, and a third subpixel including a third driving transistor driving the third light emitting element, and at least two of the first subpixel, the second subpixel, and the third subpixel may have different contact hole area densities.

In accordance with another aspect of the present disclosure, there is provided a display device comprising a red subpixel including a red light emitting element and a first driving transistor driving the red light emitting element, a green subpixel including a green light emitting element and a second driving transistor driving the green light emitting element, and a blue subpixel including a blue light emitting element and a third driving transistor driving the blue light emitting element, and the red subpixel, at least two of the green subpixel, and the blue subpixel may have different contact hole areas.

It is to be understood that both the foregoing general description and the following detailed description of the present disclosure are exemplary and explanatory and are intended to provide further explanation of the disclosure.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a block diagram schematically illustrating a configuration of a display device according to an embodiment.

FIG. 2 is a diagram illustrating an example of a pixel configuration of a display device according to an embodiment.

FIGS. 3A to 3C are diagrams illustrating a degree of dehydrogenation according to an aperture ratio of a contact hole in a driving transistor of an R/G/B subpixel according to an embodiment.

FIG. 4 is a diagram illustrating a voltage-current characteristic graph of a driving transistor for each R/G/B subpixel according to an embodiment.

FIG. 5A is a diagram illustrating a current-luminance characteristic graph for each R/G/B subpixel according to a comparative example of the related art, and FIG. 5B is a diagram illustrating a current-luminance characteristic graph for each R/G/B subpixel according to an embodiment.

FIG. 6 is a diagram illustrating an example of a pixel configuration of a display device according to an embodiment.

FIG. 7 is an equivalent circuit diagram illustrating an example of a configuration of a subpixel according to an embodiment.

FIG. 8 is an equivalent circuit diagram illustrating an example of a configuration of a subpixel according to an embodiment.

FIGS. 9A to 9C are cross-sectional views illustrating an example of a stacked structure of an R/G/B subpixel in a display device according to an embodiment.

FIGS. 10A to 10C are cross-sectional views illustrating an example of a stacked structure of an R/G/B subpixel in a display device according to an embodiment.

FIG. 11 is a diagram illustrating a ratio of a contact hole area to an area of an active layer in each subpixel of the display device according to an embodiment.

FIG. 12 is a diagram illustrating an S-factor characteristic graph according to a contact hole area ratio in a display device according to an embodiment.

FIG. 13 is cross-sectional views illustrating an example of a simplified stacking structure of an R/G/B subpixel including a white light emitting element in a display device according to an embodiment.

FIG. 14 is a diagram illustrating a current-luminance characteristic graph of the display device illustrated in FIG. 13.

### DETAILED DESCRIPTION

Advantages and features of the present disclosure, and implementation methods thereof will be clarified through the following embodiments, described with reference to the accompanying drawings. The present disclosure may, however, be embodied in different forms and should not be construed as being limited to the embodiments set forth herein. Rather, these embodiments are provided so that this disclosure will be thorough and complete, and will fully convey the scope of the present disclosure to those skilled in the art.

The shapes, sizes, ratios, angles, and numbers disclosed in the drawings for describing embodiments of the present disclosure are merely examples, and thus the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted.

In the case in which “comprise,” “have,” and “include” described in the present specification are used, another part may also be present unless “only” is used. The terms in a singular form may include plural forms unless noted to the contrary.

In construing an element, the element is construed as including an error region although there is no explicit description thereof.

In describing a positional relationship, for example, when the positional order is described as “on,” “above,” “below,” “beneath,” and “next,” the case of no contact therebetween may be included, unless “just” or “direct” is used.

If it is mentioned that a first element is positioned “on” a second element, it does not mean that the first element is essentially positioned above the second element in the figure. The upper part and the lower part of an object concerned may be changed depending on the orientation of the object. Consequently, the case in which a first element is positioned “on” a second element includes the case in which the first element is positioned “below” the second element as well as the case in which the first element is positioned “above” the second element in the figure or in an actual configuration.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc., may be used herein to describe various elements, these elements should not be limited by these terms. These terms are only used to distinguish one element from another. For example, a first element could be termed a second element, and, similarly, a second element could be termed a first element.

It should be understood that the term “at least one” includes all combinations related with any one item. For example, “at least one among a first element, a second element and a third element” may include all combinations of two or more elements selected from the first, second and third elements as well as each element of the first, second and third elements.

Features of various embodiments of the present disclosure may be partially or overall coupled to or combined with each other, and may be variously inter-operated with each other and driven technically The embodiments of the present disclosure may be carried out independently from each other, or may be carried out together in a co-dependent relationship.

Hereinafter, the aspect of the present disclosure will be described with reference to the accompanying drawings. Since a scale of each of elements shown in the accompanying drawings is different from an actual scale for convenience of description, the present disclosure is not limited to the shown scale. Further, all the components of each display apparatus, display device, and display panel according to all aspects of the present disclosure are operatively coupled and configured.

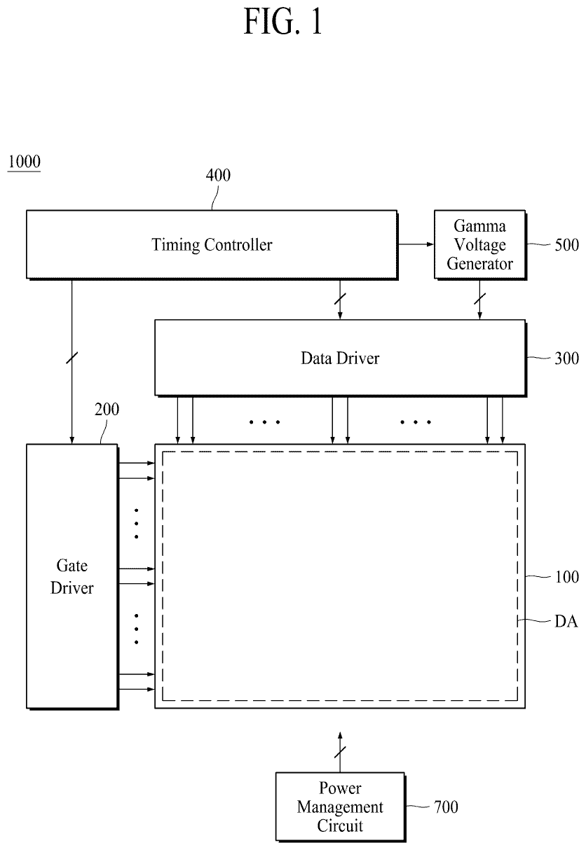

FIG. 1 is a block diagram schematically illustrating a configuration of a display device according to an embodiment.

The display device according to an embodiment may be an electroluminescent display. The electroluminescent display device may be any one of an organic light emitting diode (OLED) display device, a quantum-dot light emitting diode display device, and an inorganic light emitting diode display device.

Referring to FIG. 1, a display device 1000 according to an embodiment may include a display panel 100, a gate driver 200, a data driver 300, a timing controller 400, a gamma voltage generator 500, and a power management circuit 700. The gate driver 200 and the data driver 300 may be integrally expressed as panel drivers that drive the display panel 100. The gate driver 200, the data driver 300, the timing controller 400, the gamma voltage generator 500, and the power management circuit 700 may be integrally expressed as display drivers.

The display panel 100 may be a rigid display panel or a flexible display panel capable of shape deformation, such as a foldable, bendable, rollable, and stretchable display panel.

The display panel 100 may display an image through a pixel matrix disposed in the display area DA. In this embodiment, the display panel 100 may further include a touch sensor screen disposed in the display area DA to sense a user's touch.

Each unit pixel disposed in the display area DA may include a plurality of subpixels capable of realizing white light by emitting light of different colors. Each subpixel may be any one of a red (hereinafter referred to as R) subpixel emitting red light, a green (hereinafter referred to as G) subpixel emitting green light, a blue (hereinafter referred to as B) subpixel emitting blue light, and a white (hereinafter referred to as W) subpixel emitting white light. The unit pixel may include two, three, or four color subpixels among the R subpixel, G subpixel, B subpixel, and W subpixels. Each subpixel may include a light emitting element and a pixel circuit that independently drives the light emitting element. The light emitting element may be any one of an organic light emitting diode, a quantum dot light emitting diode, and an inorganic light emitting diode. The pixel circuit may include a plurality of transistors including a driving transistor and a switching transistor, and a storage capacitor. The pixel circuit of each subpixel may be connected to signal lines including a gate line, a data line, a power line, etc., disposed on the display panel 100.

The display panel 100 according to an embodiment may have a structure in which the current sensitivity (current distribution) of the driving transistor is different for each R/G/B subpixel in order to compensate for the difference in luminance sensitivity due to the difference in characteristics of the light emitting elements between the R/G/B subpixels. In other words, the display panel 100 according to an embodiment may have a structure in which a value of a subthreshold swing factor (hereinafter, referred to as S-factor) of the driving transistor is different for each R/G/B subpixel. At least two of the R/G/B subpixels may have different current sensitivity (current distribution) of the driving transistor. At least two of the R/G/B subpixels may have different S-factor value as of the driving transistor. Accordingly, the display panel 100 according to an embodiment may compensate for the difference in luminance sensitivity due to the difference in characteristics of the light emitting elements by causing a difference in current sensitivity (current distribution) of the driving transistor between at least two of the three-color subpixels, thereby reducing or preventing the low grayscale stain. A detailed description thereof is to be given later.

The gate driver 200 may be controlled according to a plurality of gate control signals supplied from the timing controller 400, and may individually drive the gate lines of the display panel 100. The gate driver 200 may supply a gate-on voltage to the corresponding gate line during a driving period of each gate line, and may supply a gate-off voltage to the corresponding gate line during a non-driving period of each gate line. The gate driver 200 may be embedded in the bezel region of the display panel 100 in the form of a gate in panel (GIP) formed together with thin film transistors of the display area DA.

In an embodiment, the gate driver 200 embedded in the display panel 100 may receive a plurality of gate control signals from the timing controller 400. The level shifter may receive control signals from the timing controller 400 to level-shift or perform logic processing to generate a plurality of gate control signals and supply the generated gate control signals to the gate driver 200.

The gamma voltage generator 500 may generate a plurality of reference gamma voltages having different gamma voltage levels and supply the generated gamma voltages to the data driver 300. The gamma voltage generator 500 may generate a plurality of reference gamma voltages corresponding to gamma characteristics of the display device under the control of the timing controller 400 and supply the generated gamma voltages to the data driver 300. The gamma voltage generator 500 may adjust a reference gamma voltage level according to gamma data supplied from the timing controller 400 and output the same to the data driver 300. The gamma voltage generator 500 may adjust a high potential power voltage that is a greatest gamma voltage according to peak luminance control from the timing controller 400, and may adjust a plurality of reference gamma voltages according to the adjusted high potential power voltage and output the same to the data driver 300.

The data driver 300 may be controlled according to a data control signal supplied from the timing controller 400, and may convert digital data supplied from the timing controller 400 into an analog data signal using a digital-to-analog conversion circuit. The data driver 300 may subdivide a plurality of reference gamma voltages supplied from the gamma voltage generator 500 into gamma voltages, and convert digital data into an analog data signal using the subdivided gamma voltages. The data driver 300 may supply the converted data signal to a data line of the display panel 100.

In an embodiment, the data driver 300 may additionally supply the reference voltage to the reference line of the display panel 100 according to the control of the timing controller 400. The data driver 300 may divide and supply the reference voltage into a display voltage and a sensing voltage according to the control of the timing controller 400.

In an embodiment, the data driver 300 may further include a sensing unit to sense a signal reflecting driving characteristics of each subpixel through a reference line or a power line under the control of the timing controller 400 in a voltage sensing method or a current sensing method, and transmit the sensing result to the timing controller 400.

The timing controller 400 may receive data of a source image and timing control signals from an external host system. The host system may be any one of a computer, a TV system, a set-top box, a system of a portable terminal such as a tablet or a mobile phone, and a vehicle internal system. The timing control signals may include a dot clock, a data enable signal, a vertical synchronization signal, a horizontal synchronization signal, and the like.

The timing controller 400 may control the gate driver 200 and the data driver 300 using timing control signals supplied from the host system and timing setting information stored therein. The timing controller 400 may generate a plurality of gate control signals for controlling the driving timing of the gate driver 200 and supply the generated gate control signals to the gate driver 200. The timing controller 400 may generate a plurality of data control signals for controlling the driving timing of the data driver 300 and supply the generated data control signals to the data driver 300. In an embodiment, the timing controller 400 may be represented as a controller.

The timing controller 400 may perform at least one of various image processes including image quality correction, deterioration correction, luminance correction for power consumption reduction, and the like on the input image data supplied from the host system.

In an embodiment, the timing controller 400 may further correct the image-processed data by applying a compensation value for a characteristic deviation of each subpixel stored in the memory before supplying the image-processed data to the data driver 300.

In an embodiment, the timing controller 400 may perform a sensing mode according to a request of a host system or a user or a predetermined driving sequence. The timing controller 400 may control the panel drivers 200 and 300 and the power management circuit 700 to drive the display panel 100 in a sensing mode and update compensation data stored in the memory. In the sensing mode, the timing controller 400 may sense a threshold voltage and a mobility of a driving transistor reflecting characteristics or deterioration of each subpixel of the display panel 100 through the data driver 300, and may further sense a threshold voltage of a light emitting element. The timing controller 400 may update compensation data of each subpixel by processing a sensing result.

In an embodiment, the timing controller 400 may accumulate image data of each subpixel to predict deterioration of each subpixel, and may update compensation data by sensing threshold voltages of light emitting devices only for subpixels for which relatively large deterioration is predicted.

The power management circuit 700 may generate and supply various driving voltages required for the operation of all components 100 to 700 of the display device 1000 by using an input voltage.

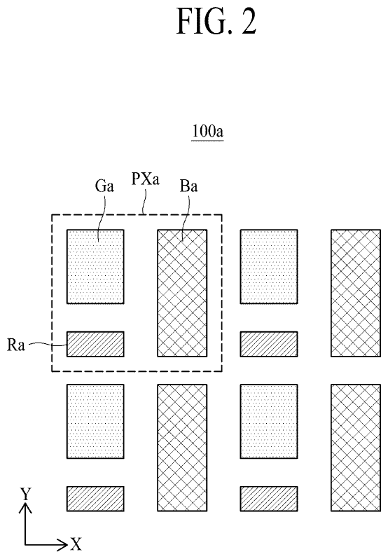

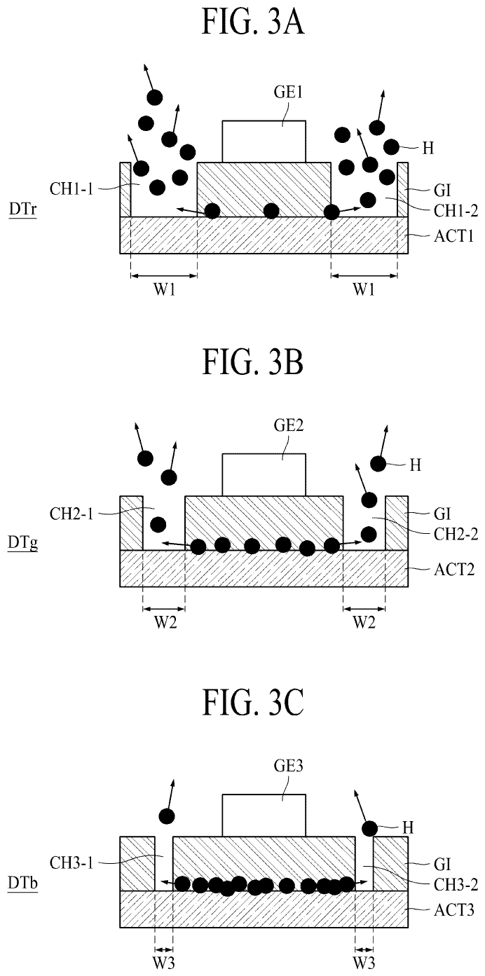

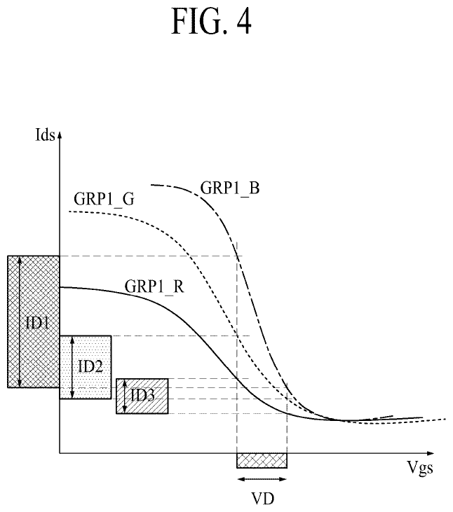

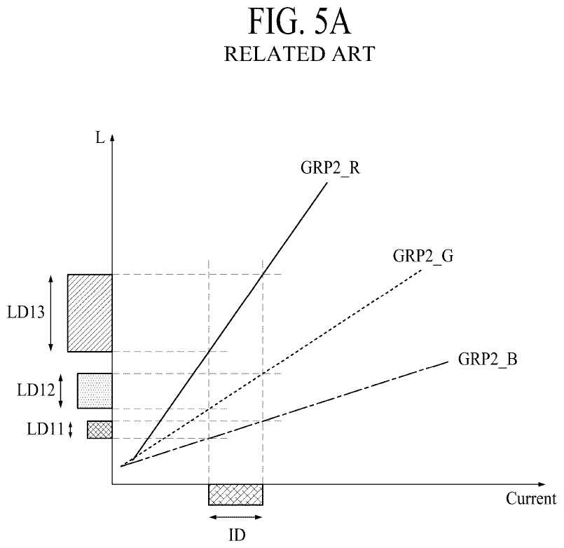

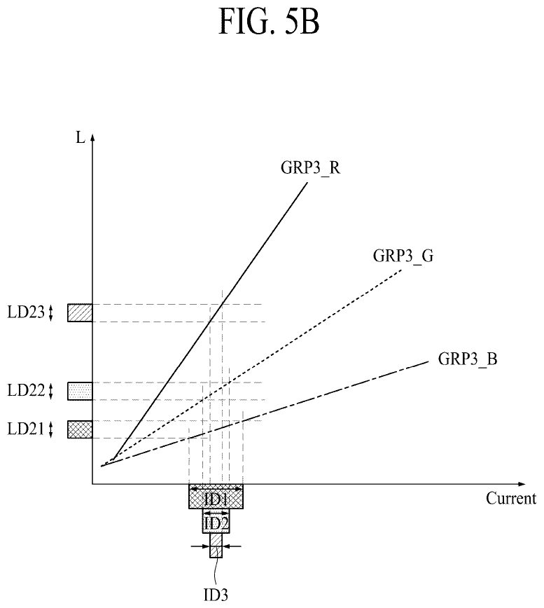

FIG. 2 is a diagram illustrating an example of a pixel configuration of a display device according to an embodiment, FIGS. 3A to 3C are diagrams illustrating a degree of dehydrogenation according to an aperture ratio of a contact hole in the driving transistor of the R/G/B subpixel according to an embodiment, FIG. 4 is a diagram illustrating a voltage-current characteristic graph of the driving transistor for each R/G/B subpixel according to an embodiment, FIG. 5A is a diagram illustrating a current-luminance characteristic graph for each R/G/B subpixel according to a comparative example of the related art, and FIG. 5B is a diagram illustrating a current-luminance characteristic graph for each R/G/B subpixel according to an embodiment.

Referring to FIG. 2, the display panel 100a according to an embodiment may include a pixel matrix in which pixels PXa including R/G/B subpixels Ra, Ga, and Ba are repeatedly arranged in a first direction X and a second direction Y. The G subpixel Ga and the R subpixel Ra may be disposed adjacent to each other in the second direction Y, and the B subpixel Ba may be disposed adjacent to the G subpixel Ga and the R subpixel Ra in the first direction X, and may be disposed in various other structures.

The R/G/B subpixels Ra, Ga, and Ba may have a form of a light emitting area in which a light emitting element emits light, and the remaining area except for the light emitting area may be a non-light emitting area in which a black matrix is disposed. In the R/G/B subpixels Ra, Ga, and Ba, the area of the light emitting area of the R subpixel Ra is the smallest in consideration of the efficiency and lifetime of the light emitting elements, the area of the light emitting area of the G subpixel Ga is larger than the area of the light emitting area of the R subpixel Ra, and the area of the light emitting area of the B subpixel Ba may be the largest, but it is not limited to the size relationship of FIG. 2. Capacitance of each light emitting element of the R/G/B subpixels Ra, Ga, and Ba may be proportional to the area of the light emitting area.

In the R/G/B subpixels Ra, Ga, and Ba according to an embodiment, in order to compensate for the difference in luminance sensitivity due to the difference in capacitance and efficiency of the R/G/B light emitting element, the S-factor value for determining current sensitivity (current distribution) according to voltage fluctuations of the driving transistor may have a structure differently applied for each R/G/B subpixel Ra, Ga, and Ba.

For this purpose, since the R/G/B subpixels Ra, Ga, and Ba according to an embodiment have different contact hole area densities for each R/G/B, the degree of dehydrogenation is applied differently for each R/G/B, and thus the S-factor value of the driving transistor may be determined differently for each R/G/B.

For example, as shown in FIGS. 3A to 3C, the driving transistors DTr, DTg, and DTb of the R/G/B subpixels have different contact hole aperture ratios for each R/G/B, and the S-factor value may be determined differently for each R/G/B as shown in FIG. 4 by differently applying the degree of dehydration. At least two of the driving transistors DTr, DTg, and DTb of the R/G/B subpixels have different contact hole aperture ratios. At least two of the driving transistors DTr, DTg, and DTb of the R/G/B subpixels have different S-factor values.

Referring to FIG. 3A, the R driving transistor DTr of the R subpixel includes a gate electrode GE1 disposed on the active layer ACT1 with the gate insulating layer GI interposed therebetween, and the gate insulating layer GI may include contact holes CH1-1 and CH1-2 exposing a source region and a drain region of the active layer ACT1, respectively. The R driving transistor DTr may have a first contact hole aperture ratio according to the first opening width W1 of each of the contact holes CH1-1 and CH1-2.

Referring to FIG. 3B, the G driving transistor DTg of a G subpixel includes a gate electrode GE2 disposed on the active layer ACT2 with the gate insulating layer GI interposed therebetween, and the gate insulating layer GI may include contact holes CH2-1 and CH2-2 exposing a source region and a drain region of the active layer ACT2, respectively. Since the second opening width W2 of each of the contact holes CH1-1 and CH1-2 is smaller than the first opening width W1, the G driving transistor DTg may have a second contact hole aperture ratio less than the first contact hole aperture ratio of the R driving transistor DTr.

Referring to FIG. 3C, the B driving transistor DTb of the B subpixel includes a gate electrode GE3 disposed on the active layer ACT3 with the gate insulating layer GI interposed therebetween, and the gate insulating layer GI may include contact holes CH3-1 and CH3-2 exposing the source region and the drain region of the active layer ACT3, respectively. Since the third opening width W3 of each of the contact holes CH1-1 and CH1-2 is smaller than the second opening width W2, the B driving transistor DTb may have a third contact hole aperture ratio less than the second contact hole aperture ratio of the G driving transistor DTg.

During the heat treatment process of the R/G/B driving transistors DTr, DTg, and DTb, hydrogen atoms H existing at the interface between the active layers ACT1, ACT2, and ACT3 and the gate insulating layer GI may be removed through the contact holes CH1-1 and CH1-2, CH2-1 and CH2-2, and CH3-1 and CH3-2. The greater the contact hole aperture ratio, the greater the degree of dehydrogenation, and the greater the degree of dehydrogenation, the greater the S-factor value.

Accordingly, the R/G/B driving transistors DTr, DTg, and DTb may have different S-factor values for each R/G/B because the degree of dehydrogenation is determined differently by structures with different contact hole aperture ratios, that is, contact hole area densities.

Referring to FIG. 4, the voltage-current (Vgs-Ids) characteristic graphs GRP1_R, GRP1_G, and GRP1_B of the R/G/B driving transistors DTr, DTg, and DTb according to an embodiment may have different slopes for each R/G/B, and the R/G/B driving transistors DTr, DTg, and DTb may have different S-factor values for each R/G/B in proportion to the reciprocal of the slopes. Accordingly, the R/G/B driving transistors DTr, DTg, and DTb may generate a difference in current distributions ID2, ID2, and ID1 according to the voltage distribution VD.

The R/G/B driving transistors DTr, DTg, and DTb may have a smaller S-factor value as the slope of the Vgs-Ids graph GRP1_R, GRP1_G, and GRP1_B increases, and a larger S-factor value as the slope decreases.

Since the graph GRP1_B of the B driving transistor DTb has the smallest first S-factor value and the largest first current distribution ID1, the graph GRP1_B may have the largest current sensitivity. the graph GRP1_G of the G driving transistor DTg has a second S-factor value greater than the first S-factor value and a second current distribution ID2 less than the first current distribution ID1, the graph GRP1_G may have a second current sensitivity less than the first current sensitivity. Since the graph GRP1_R of the R driving transistor DTr has the largest third S-factor value and the smallest third current distribution ID3, the graph GRP1_R may have the smallest third current sensitivity.

Referring to FIG. 5A, since the R/G/B subpixel according to the comparative example of the related art has the same S-factor value of the driving transistor, but has a difference in capacitance and efficiency of the light emitting element, the luminance distributions LD11, LD12, and LD13 for the current distribution ID of the driving transistor are different for each R/G/B, as shown in the current-luminance (L) characteristic graphs GRP2_R, GRP2_G, and GRP2_B of the R/G/B subpixel, indicating that the luminance sensitivity is different for each R/G/B.

On the other hand, referring to FIG. 5B, the R/G/B subpixel according to an embodiment may obtain the luminance distributions LD21, LD22, and LD23 for each R/G/B by compensating for the luminance sensitivity difference due to the capacitance and efficiency difference between the light emitting elements by differentially applying the driving transistor S-factor value as shown in the current-luminance (L) characteristic graphs GRP3_R, GRP3_G, and GRP3_B.

Accordingly, the display device according to an embodiment may compensate for the luminance sensitivity difference by optimally combining the current sensitivity difference of the driving transistor for each R/G/B subpixel and the luminance sensitivity difference of the light emitting element to reduce the difference in luminance fluctuation rate for each R/G/B, thereby improving low gray level stains.

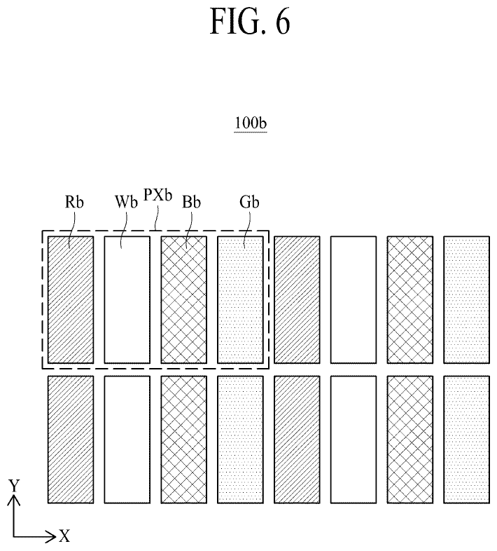

FIG. 6 is a diagram illustrating an example of a pixel configuration of a display device according to an embodiment.

Referring to FIG. 6, a display panel 100b according to an embodiment may include a pixel matrix in which a plurality of four-color-type pixels PXb, each of which further includes a white (W) subpixel Wb in the R/G/B subpixels Rb, Gb, and Bb in a display region, are repeatedly arranged in a first direction X and a second direction Y. In the four-color-type pixel PXb, the R/W/B/G subpixels Rb, Wb. Bb, and Gb may be alternately arranged in the first direction X, and may be arranged in various other forms.

In the display device according to an embodiment including four (R/W/B/G) subpixels Rb, Wb, Bb, and Gb, as shown in FIGS. 3A to 3C, the S-factor value of the driving transistor for each R/G/B subpixel Rb, Gb and Bb is differentially applied to compensate for the difference in luminance sensitivity of the light emitting element by the difference in current sensitivity of the driving transistor for each R/G/B subpixel Rb, Gb, and Bb, thereby minimizing the difference in luminance fluctuation rate for each R/G/B to improve low gray level stains. The driving transistor of the W subpixel Wb may have the same S-factor value as any one of the R/G/B subpixels Rb, Gb, and Bb.

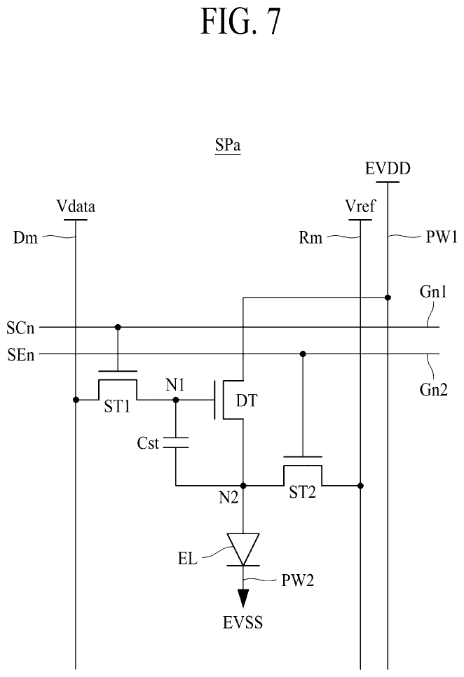

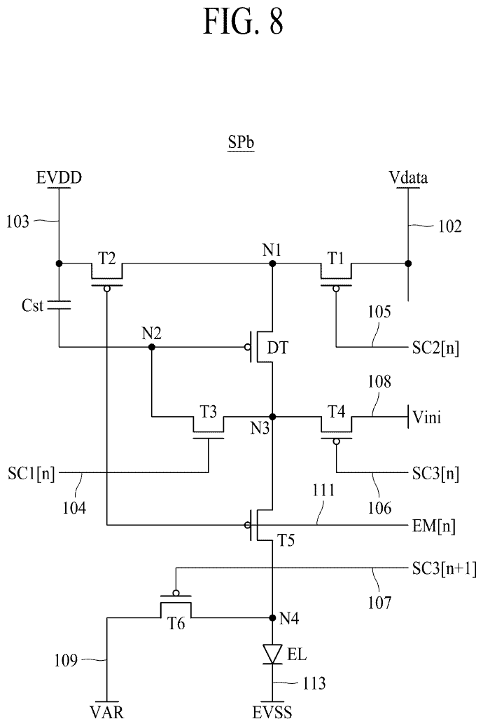

FIGS. 7 and 8 are equivalent circuit diagrams illustrating an example of a pixel circuit configuration of a subpixel according to an embodiment, and may be applied to the above-described embodiment.

Referring to FIG. 7, the subpixel SPa according to an embodiment may include the light emitting element EL connected between the first power line PW1 supplying the first power voltage EVDD (high potential power voltage) and the second power line PW2 supplying the second power voltage EVSS (low potential power voltage) and a pixel circuit including at least the first and second switching transistors ST1 and ST2, the driving transistor DT, and the storage capacitor Cst to independently drive the light emitting element EL. Each of the transistors of the pixel circuit may use at least one of a polysilicon semiconductor, an amorphous silicon semiconductor, and an oxide semiconductor.

The light emitting element EL may include an anode connected to the source node N2 of the driving transistor DT, a cathode connected to the second power line PW2, and an organic emission layer between the anode and the cathode. The anode may be independent for each subpixel, but the cathode may be a common electrode shared by all subpixels. In the light emitting element EL, when driving current is supplied from the driving transistor DT to the light emitting element EL, electrons from the cathode are injected into the organic emission layer, holes from the anode are injected into the organic emission layer, and by emitting a fluorescent or phosphorescent material by recombination of electrons and holes in the organic emission layer, light having a luminance proportional to the current value of the driving current may be generated.

The first switching transistor ST1 may be driven by the scan gate signal SCn supplied to the first gate line Gn1 from the gate driver 200 (FIG. 1), and may supply the data voltage Vdata supplied to the data line Dm from the data driver 300 (FIG. 1) to the gate node N1 of the driving transistor DT.

The second switching transistor ST2 may be driven by the sense gate signal SEn supplied to the second gate line Gn2 from the gate driver 200 (FIG. 1), and may supply the reference voltage Vref supplied to the reference line Rm from the data driver 300 (FIG. 1) to the source node N2 of the driving transistor DT. Meanwhile, in the sensing mode, the second switching transistor ST2 may provide a current in which the characteristics of the driving transistor DT or the characteristics of the light emitting element EL are reflected to the reference line Rm.

The first and second switching transistors ST1 and ST2 may be controlled by different gate lines Gn1 and Gn2 as shown in FIG. 7, or may be controlled by the same gate line.

The storage capacitor Cst connected between the gate node N1 and the source node N2 of the driving transistor DT may charge a difference voltage between the data voltage Vdata and the reference voltage Vref supplied to the gate node N1 and the source node N2 through the first and second switching transistors ST1 and ST2, respectively, as the driving voltage Vgs of the driving transistor DT, and hold the driving voltage Vgs charged during a light emission period in which the first and second switching transistors ST1 and ST2 are turned off.as the driving voltage Vgs of the driving transistor DT

The driving transistor DT may control the emission intensity of the light emitting element EL by controlling the current Ids flowing to the light emitting element EL according to the driving voltage Vgs charged in the storage capacitor Cst.

Referring to FIG. 8, a pixel circuit of a subpixel SPb according to an embodiment may include a light emitting element EL, a driving transistor DT supplying a current to the light emitting element EL, a plurality of transistors T1 to T6, and a storage capacitor Cst. Each of the transistors of the pixel circuit may use any one of a polysilicon semiconductor, an amorphous silicon semiconductor, and an oxide semiconductor.

In an embodiment, the driving transistor DT and the remaining transistors T1 to T6 may be configured by mixing a P-type polysilicon transistor and an N-type oxide transistor.

For example, the driving transistor DT and some of the transistors T1 to T3 and T5-T6 may be configured as P-type LTPS transistors with high mobility. The sampling transistor T3 may be configured as an N-type oxide transistor having a smaller leakage current than the LTPS transistor.

The light emitting element EL may include an anode connected to the drain electrode of the driving transistor DT through the light emission control transistor T5, a cathode connected to the second power line 113 supplying the second power voltage EVSS, and an organic light emitting layer between the anode and the cathode. The light emitting element EL may generate light having luminance proportional to the current value of the driving current supplied from the driving transistor DT.

The sampling transistor T3 may be controlled by the first gate line 104, and connect the second node N2 connected to the gate electrode of the driving transistor DT, with the third node N3 connected to the drain electrode of the driving transistor DT. The sampling transistor T3 may be turned on by the gate-on voltage of the first scan signal SC1[n] supplied through the first gate line 104 to connect the gate electrode with the drain electrode of the driving transistor DT in a diode structure.

The switching transistor T1 may be controlled by the second gate line 105, and may connect the data line 102 with the first node N1 connected to the source electrode of the driving transistor DT. The switching transistor T1 may be turned on by the gate-on voltage of the second scan signal SC2[n] supplied through the second gate line 105 to supply the data voltage Vdata supplied through the data line 102 to the source electrode of the driving transistor DT.

The operation control transistor T2 may be controlled by the fifth gate line 111, and may connect the first power line 103 supplying the first power voltage EVDD, with the first node N1 connected to the source electrode of the driving transistor DT. The operation control transistor T2 may be turned on by the gate-on voltage of the emission control signal EM[n] supplied through the fifth gate line 111 to supply the first power voltage EVDD supplied through the first power line 103 to the source electrode of the driving transistor DT.

The light emission control transistor T5 may be controlled by the fifth gate line 111, and may connect the third node N3 connected to the drain electrode of the driving transistor DT, with the fourth node N4 connected to the anode electrode of the light emitting element EL. The light emission control transistor T5 may be turned on by the gate-on voltage of the light emission control signal EM[n] supplied through the fifth gate line 111 to connect the drain electrode of the driving transistor DT with the anode electrode of the light emitting element EL.

The first initialization transistor T4 may be controlled by the third gate line 106, and may connect the first initialization voltage line 108 with the third node N3 connected to the drain electrode of the driving transistor DT. The first initialization transistor T4 may be turned on by the gate-on voltage of the third scan signal SC3[n] supplied through the third gate line 106 to supply the first initialization voltage Vini supplied through the first initialization voltage line 108 to the third node N3 connected to the drain electrode of the driving transistor DT.

The second initialization transistor T6 may be controlled by the fourth gate line 107, and may connect the second initialization voltage line 109 with the fourth node N4 connected to the anode of the light emitting element EL. The second initialization transistor T6 may be turned on by the gate-on voltage of the fourth gate signal SC3[n+1] supplied through the fourth gate line 107 to supply the second initialization voltage VAR supplied through the second initialization voltage line 109 to the fourth node N4 connected to the anode electrode of the light emitting element LED.

The storage capacitor Cst may be connected between the first power line 103 and the second node N2 connected to the gate electrode of the driving transistor DT. The storage capacitor Cst may charge a difference voltage between the first power voltage EVDD supplied through the first power line 103, and the data voltage Vdata supplied from the data line 102 to the second node N2 via the switching transistor T1 and the driving transistor DT and the sampling transistor T3. While the driving transistor DT is connected in a diode structure through the sampling transistor T3, the storage capacitor Cst may sample and store the threshold voltage Vth of the driving transistor DT, and may provide a data voltage in which the threshold voltage Vth is compensated to the gate electrode of the driving transistor DT. Accordingly, the storage capacitor Cst may charge a difference voltage between the first power voltage EVDD and the data voltage Vdata in which the threshold voltage Vth of the driving transistor DT is compensated as a target voltage, and may provide the charged target voltage as a driving voltage Vgs between the gate and source electrodes of the driving transistor DT. Therefore, variation in characteristics of the driving transistor DT between the subpixels may be compensated.

The driving transistor DT may control the emission intensity of the light emitting element EL by controlling the current Ids flowing to the light emitting element EL according to the driving voltage charged in the storage capacitor Cst.

Referring to FIGS. 1 and 8, in FIG. 8, the first to fourth gate lines 104, 105, 106, and 107 may be driven by a scan driver included in the gate driver 200, and the fifth gate line 111 may be driven by a light emission control driver included in the gate driver 200. The data voltage Vdata may be supplied from the data driver 300, and a first power voltage EVDD, a second power voltage EVSS, a first initialization voltage Vini, and a second initialization voltage VAR may be supplied from the power management circuit 700.

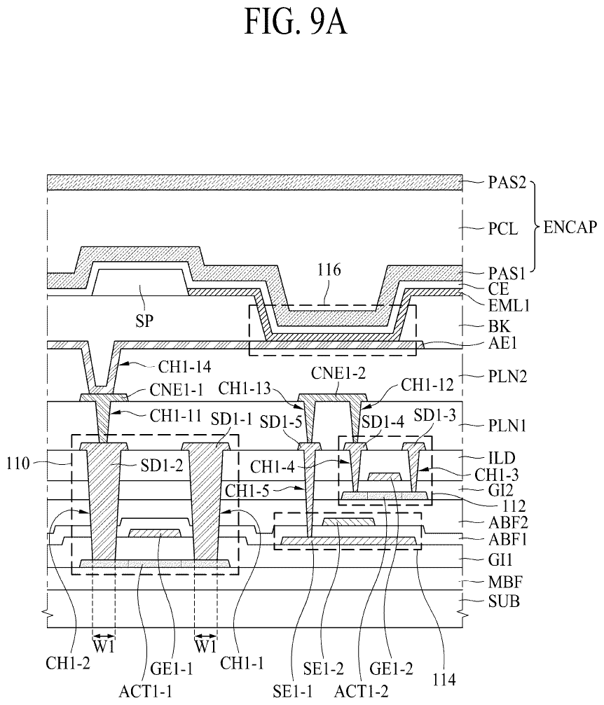

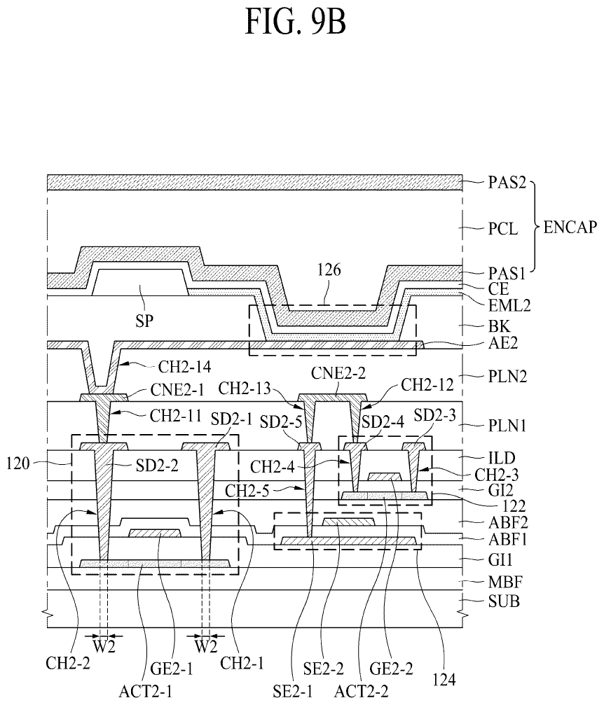

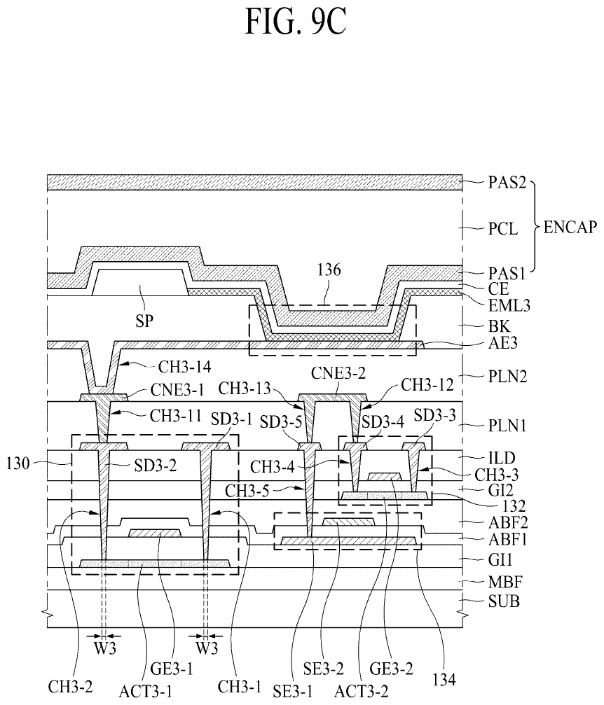

FIGS. 9A to 9C are cross-sectional views illustrating an example of a stacked structure of each of R/G/B subpixels in the display device according to an embodiment.

The R subpixel shown in FIG. 9A, the G subpixel shown in FIG. 9B, and the B subpixel shown in FIG. 9C may include a circuit element layer including driving transistors 110, 120, and 130 disposed on a substrate SUB, switching transistors 112, 122, and 132, and storage capacitors 114, 124, and 134, a light emitting element layer including R, G, B light emitting elements 116, 126, and 136 disposed on the circuit element layer, and an encapsulation layer ENCAP disposed on the light emitting element layer.

In an embodiment, a touch sensor array including a plurality of touch electrodes may be further disposed on the encapsulation layer ENCAP. A color filter array including a color filter and a black matrix may be further disposed on the touch sensor array, or a lens array may be further disposed on the touch sensor array.

Referring to FIGS. 9A to 9C, the driving transistors 110, 120, and 130 of the R/G/B subpixel according to an embodiment may have different S-factor values for each R/G/B due to structures having different contact hole aperture ratios, that is, different contact hole area densities, as described above. The driving transistors 110, 120, and 130 may be implemented as polysilicon transistors, and the switching transistors 112, 122, and 132 may be implemented as oxide transistors.

The substrate SUB may include a plastic substrate or a glass substrate. The plastic substrate may be formed of a flexible material. For example, the substrate SUB may include at least one organic insulating material among an acrylic resin, an epoxy resin, a siloxane resin, a polyimide resin, and a polyamide resin.

A lower buffer layer MBF may be disposed on the substrate SUB. The lower buffer layer MBF may prevent an impurity such as hydrogen from being introduced into the semiconductor layers ACT1-1, ACT2-1, and ACT3-1 through the substrate SUB. The lower buffer layer MBF may include an inorganic insulating material. For example, the lower buffer layer MBF may include an oxide-based insulating material such as silicon oxide SiOx or aluminum oxide Al₂O₃.

In an embodiment, a barrier layer capable of blocking particle inflow may be further disposed between the substrate SUB and the lower buffer layer MBF. The barrier layer may be formed of a multi-barrier layer in which at least one organic insulating layer and at least one inorganic insulating layer are alternately stacked.

The driving transistors 110, 120, and 130 may include semiconductor layers ACT1-1, ACT2-1, and ACT3-1 disposed on the lower buffer layer MBF, gate electrodes GE1-1, GE2-1, and GE3-1 overlapping the channel regions of the semiconductor layers ACT1-1, ACT2-1, and ACT3-1 with the first gate insulating layer GI1 interposed therebetween, first electrodes (source electrodes) SD1-1, SD2-1, and SD3-1 respectively connected to one-side conductive regions (source regions) of the semiconductor layers ACT1-1, ACT2-1, and ACT3-1 through the contact holes CH1-1, CH2-1, and CH3-1, and second electrodes (drain electrodes) SD1-2, SD2-2, and SD3-2 respectively connected to another-side conductive regions (drain regions) of the semiconductor layers ACT1-1, ACT2-1 and ACT3-1 through the contact holes CH1-2, CH2-2 and CH3-2. The semiconductor layers ACT1-1, ACT2-1, and ACT3-1 may be composed of low-temperature polysilicon (LPTS), and the conductive region may be a region doped with impurities.

The driving transistors 110, 120, and 130 may have different S-factor values for each R/G/B because the opening widths W1, W2, and W3 of the contact holes CH1-2, CH2-2, and CH3-2 have different structures for each R/G/B.

First and second upper buffer layers ABF1 and ABF2 may be stacked on the gate electrodes GE1-1, GE2-1, and GE3-1 of the driving transistors 110, 120, and 130, and the switching transistors 112, 122, and 132 may be disposed on the second upper buffer layer ABF2. The upper buffer layers ABF1 and ABF2 may include an inorganic insulating material such as silicon oxide SiO2 and silicon nitride SiNx.

The switching transistors 112, 122, and 132 may include may include semiconductor layers ACT1-2, ACT2-2, and ACT3-2 disposed on the second upper buffer layer ABF2, gate electrodes GE1-2, GE2-2, and GE3-2 overlapping the channel regions of the semiconductor layers ACT1-2, ACT2-2, and ACT3-2 with the second gate insulating layer GI2 interposed therebetween, first electrodes (source electrodes) SD1-3, SD2-3, and SD3-3 respectively connected to one-side conductive regions (source regions) of the semiconductor layers ACT1-2, ACT2-2, and ACT3-2 through the contact holes CH1-3, CH2-3, and CH3-3, and second electrodes (drain electrodes) SD1-4, SD2-4, and SD3-4 respectively connected to another-side conductive regions (drain regions) of the semiconductor layers ACT1-2, ACT2-2 and ACT3-2 through the contact holes CH1-4, CH2-4 and CH3-4. The semiconductor layers ACT1-2, ACT2-2, and ACT3-2 may include an oxide semiconductor layer including at least one of an IZO (InZnO)-based, an IGO (InGaO)-based, an ITO (InSnO)-based, an IGZO (InGaZnO)-based, an IGZTO (InGaZnSnO)-based, a GZO (GaZnO)-based, and an ITZO (InSnZnO)-based semiconductor layer, the conductive regions of the semiconductor layers ACT1-2, ACT2-2, and ACT3-2 may be regions doped with impurities.

An interlayer insulating layer ILD may be disposed on the gate electrodes GE1-2, GE2-2, and GE3-2 of the switching transistors 112, 122, and 132. The interlayer insulating layer ILD may include an inorganic insulating material such as silicon oxide SiO2 or silicon nitride SiNx.

The first electrodes (source electrodes) SD1-1, SD2-1, and SD3-1 and the second electrodes (drain electrodes) SD1-2, SD2-2, and SD3-2 of the driving transistors 110, 120, and 130, and the first electrodes (source electrodes) SD1-3, SD2-3, and the second electrodes (drain electrodes) SD1-4, SD2-4, and SD3-4 of the switching transistors 112, 122, and 132 may be disposed on the interlayer insulating layer ILD.

The contact holes CH1-1, CH1-2, CH2-1, CH2-2, CH3-1, and CH3-2 of the driving transistors 110, 120, and 130 may be formed through the interlayer insulating layer ILD, the second gate insulating layer GI2, the upper buffer layers ABF2 and ABF1, and the first gate insulating layer GI1.

The contact holes CH1-3, CH1-4, CH2-3, CH2-4, CH3-3, and CH3-4 of the switching transistors 112, 122, and 132 may be formed through the interlayer insulating layer ILD and the second gate insulating layer GI2.

The first and second planarization layers PLN1 and PLN2 may be disposed on the driving transistors 110, 120, and 130 and the switching transistors 112, 122, and 132, and first connection electrodes CNE1-1, CNE2-1, CNE3-1 and second connection electrodes CNE1-2, CNE2-2, and CNE3-2 may be disposed between the first planarization layer PLN1 and the second planarization layer PLN2. The planarization layers PLN1 and PLN2 may include an organic insulating material.

The storage capacitors 114, 124, and 134 may include lower storage electrodes SE1-1, SE2-1, and SE3-1 disposed on the first gate insulating layer GI1 and upper storage electrodes SE1-2, SE2-2, and SE3-2 disposed on the first upper buffer layer ABF1. The lower storage electrodes SE1-1, SE2-1, and SE3-1 may be connected to the gate electrodes GE1-1, GE2-1, and GE3-1 of the driving transistors 110, 120, and 130. The lower storage electrodes SE1-1, SE2-1, and SE3-1 may be connected to the second electrodes SD1-4, SD2-4, and SD3-4 of the switching transistors 112, 122, and 132 through the third electrodes SD1-5, SD2-5, and SD3-5 and the second connection electrodes CNE1-2, CNE2-2, and CEN3-2. the third electrodes SD1-5, SD2-5, and SD3-5 may be connected to the lower storage electrodes SE1-1, SE2-1, and SE3-1 through the contact holes CH1-5, CH2-5, and CH3-5 penetrating the first upper buffer layer ABF1 from the interlayer insulating layer ILD, and may be connected to the second connection electrodes CNE1-2, CNE2-1, and CNE3-1 through contact holes CH1-13, CH2-13, and CH3-13 penetrating the first planarization layer PLN1. The second connection electrodes CNE1-2, CNE2-2, and CNE3-2 may be connected to the second electrodes SD1-4, SD2-4, and SD3-4 of the switching transistors 112, 122, and 132 through contact holes CH1-12, CH2-12, and CH3-12 penetrating the first planarization layer PLN1.

The driving transistors 110, 120, and 130 may be connected to the light emitting elements 116, 126, and 136 through the first connection electrodes CNE1-1, CNE1-2, and CNE1-2. The first connection electrodes CNE1-1, CNE1-2, and CNE1-2 may be connected to the second electrodes SD1-2, SD2-2, and SD3-2 of the driving transistors 110, 120, and 130 through the contact holes CH1-11, CH2-11, and CH3-11 penetrating the first planarization layer PLN1, and may be connected to the anode electrodes (the first electrodes) AE1, AE2, and AE3 of the light emitting elements 116, 126, and 136 through the contact holes CH1-14, CH2-14, and CH3-14 penetrating the second planarization layer PLN2.

A light emitting element layer including the light emitting elements 116, 126, and 136, the bank layer BK, and the spacer SP may be disposed on the second planarization layer PLN2.

The light emitting elements 116, 126, and 136 may include anode electrodes AE1, AE2, and AE3 disposed on the second planarization layer PLN2, light emitting stacks EML1, EML2, and EML3, and a cathode electrode (second electrode) CE. The anode electrodes AE1, AE2, and AE3 may be separated for each R/G/B subpixel and independently disposed. The anode electrodes AE1, AE2, and AE3 may be formed in a plurality of conductive layer structures having high reflectivity. For example, the anode electrodes AE1, AE2, and AE3 may be formed in a stacked structure Ti/Al/Ti of aluminum Al and titanium Ti, a stacked structure ITO/Al/ITO of aluminum Al and indium tin oxide ITO, or a stacked structure ITO/APC/ITO of APC and ITO. APC is an alloy of silver Ag, palladium Pd, and copper Cu.

The bank layer BK having an opening exposing the anode electrodes AE1, AE2, and AE3 on the second planarization layer PLN2 and covering ends of the anode electrodes AE1, AE2, and AE3 may be disposed on the anode electrodes AE1, AE2, and AE3. The opening of the bank layer BK may be defined as a light emitting area, and the area in which the bank layer BK is disposed may be defined as a non-light emitting area. The bank layer BK surrounding the light emitting area may be formed in a single layer structure or a double layer structure. the spacer SP having an opening wider than the opening of the bank layer BK may be further disposed on the bank layer BK. The spacer SP may support a fine metal mask FMM, which is a deposition mask, when forming the light emitting stacks EML1, EML2, and EML3. The bank layer BK and the spacer SP may be formed of an organic insulating material. The bank layer BK may include a light blocking material to block light leakage between adjacent pixels and reduce reflection of external light.

The light emitting stacks EML1, EML2, and EML3 may be formed by stacking in the order of a hole control layer, a light emitting layer, and an electron control layer, or in the reverse order. The hole control layer may include at least a hole transport layer among the hole injection layer and the hole transport layer, and the electron control layer may include at least an electron transport layer among the electron transport layer and the electron injection layer. The light emitting layers of the light emitting stacks EML1, EML2, and EML3 may generate red light, green light, and blue light, respectively. The light emitting stacks EML1, EML2, and EML3 overlapping the anode electrodes AE1, AE2, and AE3 may be disposed to partially overlap an end portion of the bank layer BK.

The cathode electrodes CE of the light emitting elements 116, 126, and 136 may be common electrodes disposed on the light emitting stacks EML1, EML2, and EML3 and connected along surfaces of the bank layer BK and the spacer SP. The cathode electrode CE may be formed of a conductive material or a semi-transmissive conductive material having high light transmittance. For example, the cathode electrode CE may be formed of a transparent conductive material such as ITO or IZO. The cathode electrode CE may be formed of a semi-transmissive metal material such as magnesium Mg, silver Ag, or alloys thereof. A capping layer may be further disposed on the cathode electrode CE to increase light resonance and light emission efficiency of the light emitting elements 116, 126, and 136.

The encapsulation layer ENCAP for sealing the light emitting element layer may be disposed on the light emitting element layer to prevent penetration of moisture or oxygen to the light emitting elements 116, 126, and 136 and to cover particles to prevent flow. The encapsulation layer ENCAP may have a stacked structure of a first and second inorganic encapsulation layers PAS1, and PAS2 and an organic encapsulation layer PCL disposed between the first and second inorganic encapsulation layers PAS1 and PAS2. The inorganic encapsulation layers PAS1 and PAS2 may prevent penetration of moisture or oxygen from the outside. The organic encapsulation layer PCL may serve to cover particles and buffer stress between layers when the display panel is bent.

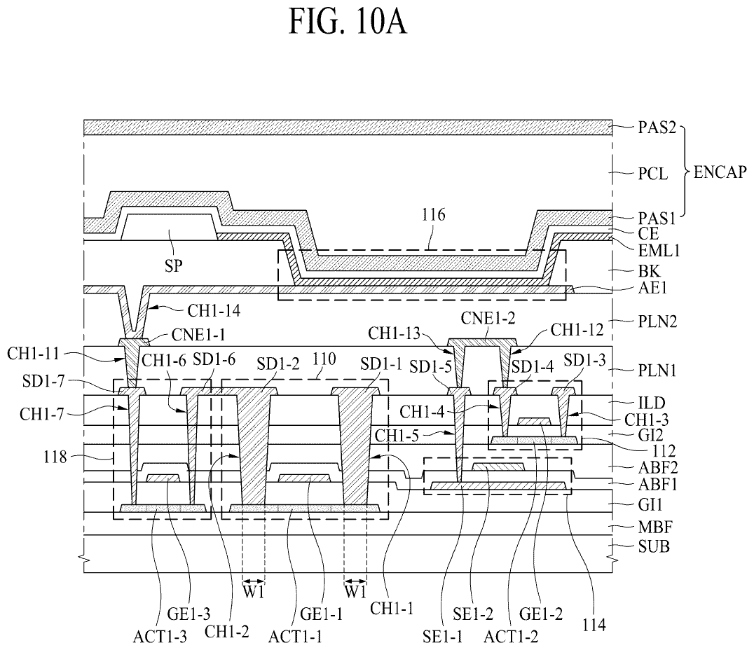

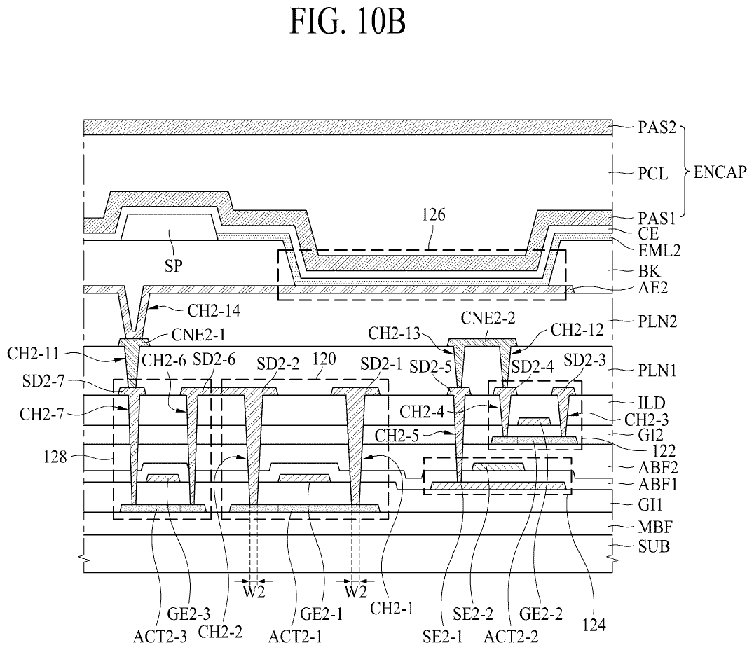

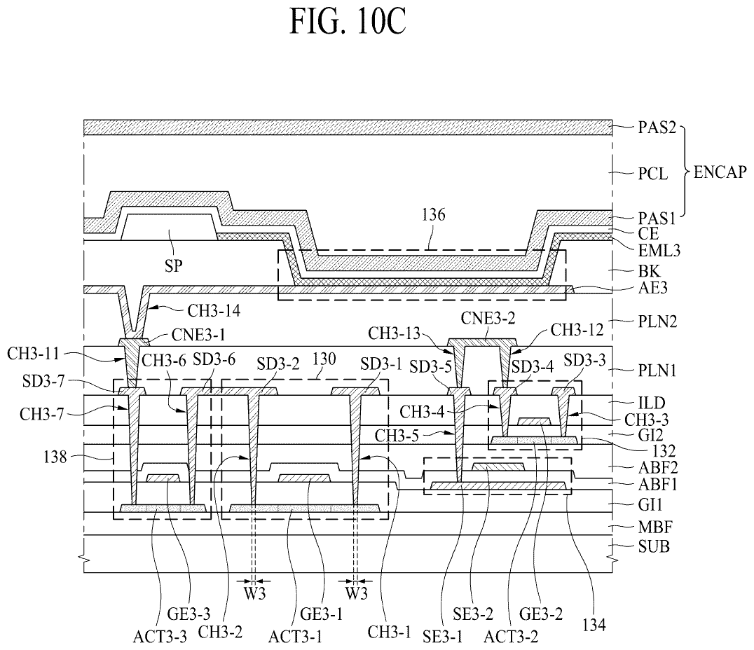

FIGS. 10A to 10C are cross-sectional views illustrating an example of a stacked structure of each of R/G/B subpixels in the display device according to an embodiment.

Since the R/G/B subpixels shown in FIGS. 10A to 10C additionally include light emission control transistors 118, 128, and 138 in comparison with the R/G/B subpixels shown in FIGS. 9A to 9C, hereinafter, description of repeated components of FIGS. 9A to 9C will be omitted.

Referring to FIGS. 10A to 10C, the driving transistors 110, 120, and 130 having different contact hole aperture ratios for each R/G/B subpixel may be connected to the light emitting elements 116, 126, and 136 through the light emission control transistors 118, 128, and 138. The light emission control transistors 118, 128, and 138 and the driving transistors 110, 120, and 130 may be implemented as polysilicon transistors, and the switching transistors 112, 122, and 132 may be implemented as oxide transistors. The switching transistors 112, 122, and 132 may correspond to the sampling transistor T3 shown in FIG. 8.

The light emission control transistors 118, 128, and 138 may include semiconductor layers ACT1-3, ACT2-3, and ACT3-3 disposed on the lower buffer layer MBF, gate electrodes GE1-3, GE2-3, and GE3-3 overlapping the channel regions of the semiconductor layers ACT1-3, ACT2-3, and ACT3-3 with the first gate insulating layer GI1 interposed therebetween, first electrodes (source electrodes) SD1-6, SD2-6, and SD3-6 respectively connected to one-side conductive regions (source regions) of the semiconductor layers ACT1-3, ACT2-3, and ACT3-3 through the contact holes CH1-6, CH2-6, and CH3-6, and second electrodes (drain electrodes) SD1-7, SD2-7, and SD3-7 respectively connected to another-side conductive regions (drain regions) of the semiconductor layers ACT1-3, ACT2-3, and ACT3-3 through the contact holes CH1-7, CH2-7 and CH3-7. The semiconductor layers ACT1-3, ACT2-3, and ACT3-3 may be composed of low-temperature polysilicon (LPTS), and the conductive region may be a region doped with impurities.

The first electrodes (source electrodes) SD1-6, SD2-6, and SD3-6 of the light emission control transistors 118, 128, and 138 may be connected to the second electrodes SD1-2, SD2-2, and SD3-2 of the driving transistors 110, 120, and 130. The second electrodes (drain electrodes) SD1-7, SD2-7, and SD3-7 of the light emission control transistors 118, 128, and 138 may be connected to the anode electrodes AE1, AE2, and AE3 of the light emitting elements 116, 126, and 136 through the first connection electrode CNE1-1.

As such, the display device according to some embodiments may compensate for the luminance sensitivity difference of the R/G/B light emitting elements by differently applying the S-factor values of the driving transistors 110, 120, and 130 for each R/G/B subpixel, thereby reducing the difference in luminance fluctuation rate for each R/G/B (see Table 1)

TABLE 1

| | Condition | R | G | B |
|---|---|---|---|---|
| Efficiency of light | | 148 | 374 | 16.6 |
| emitting elements | | | | |
| S-factor | Comparative | 0.5 | 0.5 | 0.5 |
| | Embodiment | | | |
| | Example | 0.6 | 0.5 | 0.2 |
| Luminance | Comparative | 19% | 15% | 5% |
| Fluctuation Rate | Embodiment | | | |
| | Example | 17% | 16% | 14% |

Referring to Table 1, in an example in which the S-factor values 0.6, 0.5, and 0.2 of the R/G/B driving transistors 110, 120, and 130 are differentially applied, when the gate-source voltage Vgs of the driving transistors 110, 120, and 130 is shifted by 0.2 V, it may be seen that the difference in luminance fluctuation rates (17, 16%, 14%) is reduced even though the efficiency (148.374. 16.6) of the R/G/B light emitting element is different compared to the same comparative embodiments.

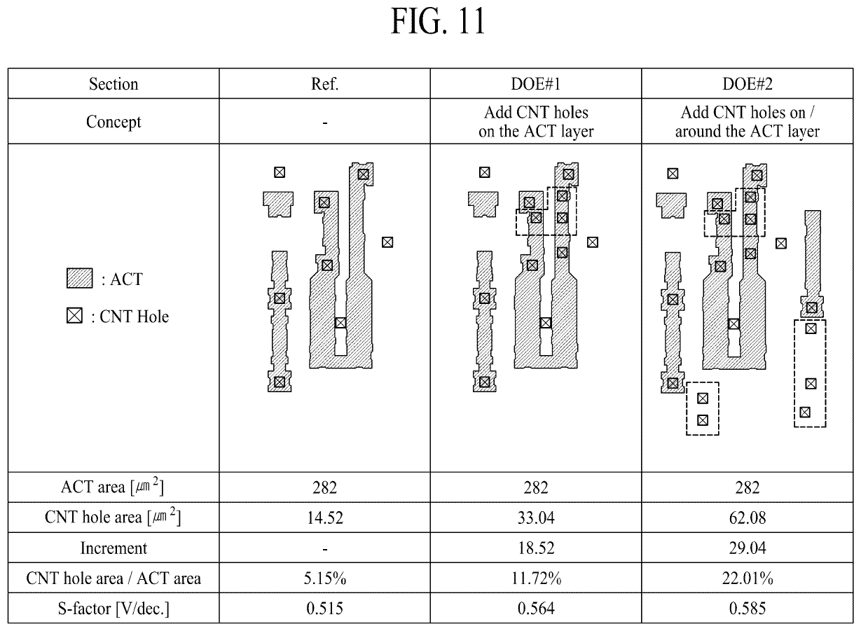

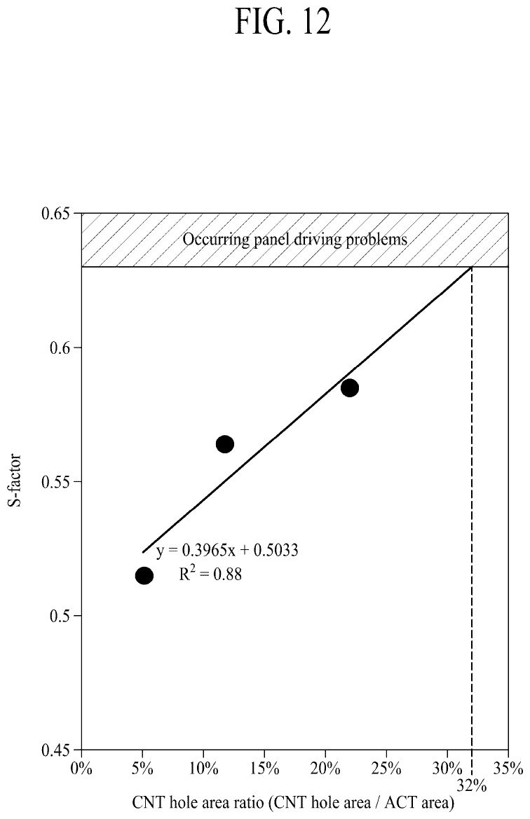

FIG. 11 is a diagram illustrating a contact hole area ratio to an area of a semiconductor layer in each subpixel of a display device according to an embodiment, and FIG. 12 is a diagram illustrating an S-factor characteristic graph according to a contact hole area ratio in a display device according to an embodiment.

Referring to FIG. 11, it may be seen that the S-factor value of the driving transistor is improved in the first and second embodiments DOE #1 and DOE #2 in which the area ratio of the contact hole CNT hole to the area of the semiconductor layer ACT disposed in one subpixel is increased compared to the reference Ref.

In the first embodiment DOE #1, it may be seen that the S-factor value of the driving transistor is improved (increased) by increasing the area ratio of the contact hole CNT hole to the area of the semiconductor layer ACT in the subpixel in which the contact hole area density is increased by adding the contact holes CNT hole to the upper portion of the semiconductor layer ACT compared to the reference Ref.

In the second embodiment DOE #2, it may be seen that the S-factor value of the driving transistor is improved (increased) by increasing the area ratio of the contact hole CNT hole to the area of the semiconductor layer ACT in the subpixel in which the contact hole area density is increased compared to the reference Ref and the first embodiment DOE #1 by adding the contact holes CNT hole to the upper portion of the semiconductor layers ACT and the periphery of the semiconductor layers ACT compared to the reference Ref.

This is because not only the contact holes CNT hole located above the semiconductor layer ACT, but also the contact holes CNT hole that do not overlap the semiconductor layer ACT are additionally disposed on the periphery of the semiconductor layer ACT, and hydrogen atoms present at the interface of the gate insulating layer are removed through the contact holes CNT hole during the heat treatment process, thereby increasing the degree of dehydrogenation.

In the display device according to an embodiment, the R subpixel may have a first contact hole area ratio, the G subpixel may have a second contact hole area ratio smaller than the first contact hole area ratio, and the B subpixel may have a third contact hole area ratio smaller than the second contact hole area ratio. The W subpixel may have the same contact hole area ratio as any one of the first to third contact hole area ratios.

For example, in FIG. 11, the second embodiment DOE #2 may be the first contact hole area ratio of the R subpixel, the first embodiment DOE #1 may be the second contact hole area ratio of the G subpixel, and the reference Ref. may be the third contact hole area ratio of the B subpixel.

Referring to FIG. 12, it may be seen that the S-factor value of the driving transistor increases and improves as the area ratio of the contact hole CNT hole to the area of the semiconductor layer ACT in one subpixel increases. However, if the area of the contact hole CNT hole within one subpixel exceeds 32% of the area of the semiconductor layer ACT, panel driving problems may occur, so it may be limited to less than 32%. In addition, the area ratio of the contact hole CNT hole to the area of the semiconductor layer ACT of one subpixel may be limited to 5% or more to improve the S-factor value compared to Comparative Example Ref.

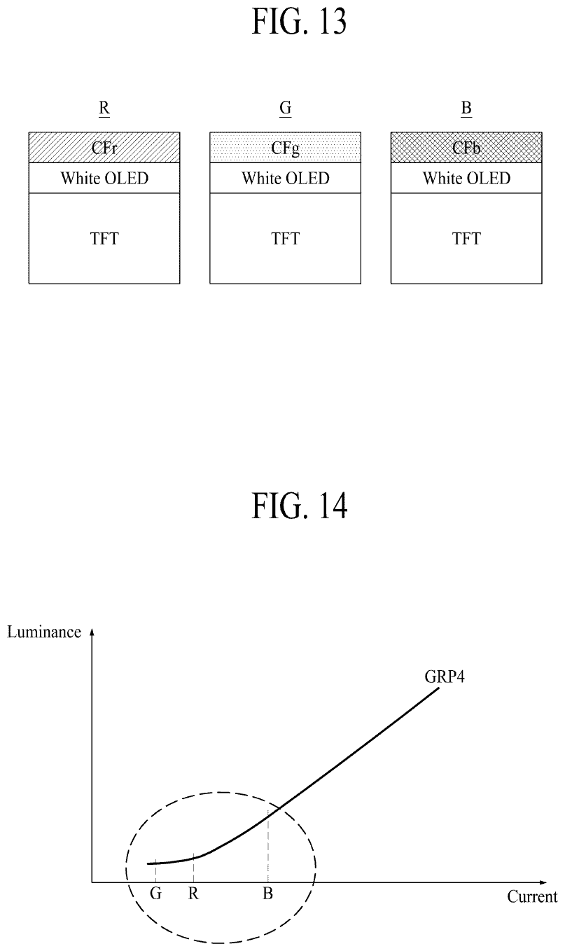

FIG. 13 is cross-sectional views schematically illustrating an example of a stacked structure of an R/G/B subpixel including a white light emitting element in a display device according to an embodiment, and FIG. 14 is a diagram illustrating a current-luminance characteristic graph of the display device shown in FIG. 13.

Referring to FIG. 13, the R/G/B subpixel of the display device according to an embodiment may have a structure in which a white light emitting element OLED is disposed on the transistor TFT and an R/G/B color filter CFr, CFg, and CFb is disposed on the white light emitting element OLED.

Referring to FIGS. 13 and 14, even when the white light emitting device OLED is applied to the R/G/B subpixel, the luminance sensitivity of each R/G/B subpixel may vary because the R/G/B efficiency of the white light emitting diode OLED is different in the low grayscale area as shown in the current-luminance characteristic graph GRP4. In order to compensate for the luminance sensitivity difference for each R/G/B subpixel, the display device according to an embodiment may differently apply the S-factor value of the driving transistor for each R/G/B subpixel even when the white light emitting diode OLED is used, thereby generating the current sensitivity difference.

Accordingly, the display device according to an embodiment may improve image quality by improving low grayscale stains by complementarily combining the luminance sensitivity difference of the light emitting element and the current sensitivity difference of the driving transistor for each R/G/B subpixel to reduce the difference in the luminance fluctuation rate.

According to an embodiment of the present disclosure, the display device according to some embodiments may compensate for the difference in luminance sensitivity between at least two of R/G/B subpixels by differently applying the S-factor value of the driving transistor for each of the at least two of the R/G/B subpixels, thereby reducing the difference in luminance variability between at least two of the R/G/B subpixels.

According to an embodiment of the present disclosure, the display device according to some embodiments may compensate for the difference in luminance sensitivity by generating a difference in current sensitivity (current distribution) between at least two of the R/G/B subpixels by differently applying the contact hole area density for each of the at least two of the R/G/B subpixels.

According to an embodiment of the present disclosure, the display device according to some embodiments may improve image quality by reducing or preventing low grayscale stains by compensating for luminance sensitivity differences by generating current sensitivity differences between the at least two of the R/G/B subpixels, and may further provide improved image quality even with low power consumption by reducing or preventing low grayscale stains.

As described above, the display device according to some embodiments of the present disclosure may include a first subpixel including a first light emitting element emitting light of a first color and a first driving transistor driving the first light emitting element, a second subpixel including a second light emitting element emitting light of a second color and a second driving transistor driving the second light emitting element, and a third subpixel including a third driving transistor driving the third light emitting element, and at least two of the first subpixel, the second subpixel, and the third subpixel may have different contact hole area densities.

In the display device according to some embodiments, the first to third driving transistors may have different current sensitivities according to voltage fluctuations.

In the display device according to some embodiments, the first to third driving transistors may have different current distributions according to voltage fluctuations.

In the display device according to some embodiments, wherein the first to third driving transistors may have different S-factor values.

In the display device according to some embodiments, the first to third subpixels may be red, green, and blue subpixels, respectively, the red subpixel may have a first light emitting area, the green subpixel may have a second light emitting area larger than the first light emitting area, and the blue subpixel may have a third light emitting area larger than the second light emitting area.

In the display device according to some embodiments, the red subpixel may have a first contact hole area density, the green subpixel may have a second contact hole area density smaller than the first contact hole area density, and the blue subpixel may have a third contact hole area density smaller than the second contact hole area density.

In the display device according to some embodiments, the red subpixel may have a first degree of dehydrogenation, the green subpixel may have a second degree of dehydrogenation smaller than the first degree of dehydrogenation, and the blue subpixel may have a third degree of dehydrogenation smaller than the second degree of dehydrogenation.

In the display device according to some embodiments, each of the first to third light emitting elements included in the red, green, and blue subpixels may be a red light emitting element, a green light emitting element, and a blue light emitting element.

In the display device according to some embodiments, each of the first to third light emitting elements included in the red, green, and blue subpixels may include white light emitting elements in common and includes red, green, and blue color filters, respectively.

The display device according to some embodiments further may include a white subpixel including a white light emitting element and a fourth driving transistor driving the white light emitting element, wherein the fourth driving transistor may have a same S-factor value as any one of the first to third driving transistors.

The display device according to some embodiments of the present disclosure may include a red subpixel including a red light emitting element and a first driving transistor driving the red light emitting element, a green subpixel including a green light emitting element and a second driving transistor driving the green light emitting element, and a blue subpixel including a blue light emitting element and a third driving transistor driving the blue light emitting element, and at least two of the red subpixel, the green subpixel, and the blue subpixel may have different contact hole areas.

In the display device according to some embodiments, each of the red, green, and blue subpixels may have different ratios of the contact hole area to the same semiconductor layer area.

In the display device according to some embodiments, the contact hole area may include an area of a contact hole overlapping the semiconductor layer in each of red, green, and blue subpixels.

In the display device according to some embodiments, the contact hole area further may include an area of a contact hole disposed around the semiconductor layer in each of the red, green, and blue subpixels.

In the display device according to some embodiments, the red subpixel may have a first light emitting area, the green subpixel may have a second light emitting area larger than the first light emitting area, and the blue subpixel may have a third light emitting area larger than the second light emitting area.

In the display device according to some embodiments, an efficiency of the green light emitting element may be greater than an efficiency of the red light emitting element, and the efficiency of the red light emitting element may be greater than an efficiency of the blue light emitting element.

In the display device according to some embodiments, the red subpixel may have a first contact hole area, the green subpixel may have a second contact hole area smaller than the first contact hole area, and the blue subpixel may have a third contact hole area smaller than the second contact hole area.

In the display device according to some embodiments, the first driving transistor may have a first S-factor value, the second driving transistor may have a second S-factor value smaller than the first S-factor value, and the third driving transistor may have a third S-factor value smaller than the second S-factor value.

The display device according to some embodiments further may include a white subpixel including a white light emitting element and a fourth driving transistor driving the white light emitting element, wherein the fourth driving transistor may have the same S-factor value as any one of the first to third driving transistors.

In the display device according to some embodiments, a ratio of the contact hole area to the semiconductor layer area in each of the red, green, and blue subpixels may be 5% or more and 32% or less.

The display device according to one or more embodiments of the present disclosure may be applied to various electronic devices. For example, the display device according to one or more embodiments of the present disclosure may be applied to a mobile device, a video phone, a smart watch, a watch phone, a wearable device, a foldable device, a rollable device, a bendable device, a flexible device, a curved device, an electronic diary, electronic book, a portable multimedia player (PMP), a personal digital assistant (PDA), MP3 player, a mobile medical device, a desktop PC, a laptop PC, a netbook computer, a workstation, a navigator, a vehicle navigator, a vehicle display device, a television, a wall paper display device, a signage device, a game device, a notebook computer, a monitor, a camera, a camcorder, and home appliances.

The above-described feature, structure, and effect of the present disclosure are included in at least one embodiment of the present disclosure, but are not limited to only one embodiment. Furthermore, the feature, structure, and effect described in at least one embodiment of the present disclosure may be implemented through combination or modification of other embodiments by those skilled in the art. Therefore, content associated with the combination and modification should be construed as being within the scope of the present disclosure.

It will be apparent to those skilled in the art that various substitutions, modifications, and variations are possible within the scope of the present disclosure without departing from the spirit and scope of the present disclosure. Therefore, the scope of the present disclosure includes those represented by the following claims, and all changes or modifications derived from the meaning, range and equivalent concept of the claims should be interpreted as being included in the scope of the present disclosure.

The various embodiments described above can be combined to provide further embodiments. Aspects of the embodiments can be modified, if necessary to employ concepts of the various embodiments to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a first subpixel including a first light emitting element configured to emit light of a first color and a first driving transistor configured to drive the first light emitting element;
a second subpixel including a second light emitting element configured to emit light of a second color and a second driving transistor configured to drive the second light emitting element; and
a third subpixel including a third light emitting element configured to emit light of a third color and a third driving transistor configured to drive the third light emitting element,
wherein at least two of the first subpixel, the second subpixel, or the third subpixel have different contact hole area densities.

2. The display device according to claim 1, wherein the first, second and third driving transistors have different current sensitivities to voltage fluctuations.

3. The display device according to claim 1, wherein the first, second, and third driving transistors have different current distributions according to voltage fluctuations.

4. The display device according to claim 1, wherein the first, second, and third driving transistors have different S-factor values.

5. The display device according to claim 4, wherein the first, second, and third subpixels are red, green, and blue subpixels, respectively,
the red subpixel has a first light emitting area,
the green subpixel has a second light emitting area larger than the first light emitting area, and
the blue subpixel has a third light emitting area larger than the second light emitting area.

6. The display device according to claim 5, wherein the red subpixel has a first contact hole area density,
the green subpixel has a second contact hole area density smaller than the first contact hole area density, and
the blue subpixel has a third contact hole area density smaller than the second contact hole area density.

7. The display device according to claim 6, wherein the red subpixel has a first degree of dehydrogenation,
the green subpixel has a second degree of dehydrogenation smaller than the first degree of dehydrogenation, and
the blue subpixel has a third degree of dehydrogenation smaller than the second degree of dehydrogenation.

8. The display device according to claim 5, wherein each of the first, second, and third light emitting elements included in the red, green, and blue subpixels is a red light emitting element, a green light emitting element, and a blue light emitting element, respectively.

9. The display device according to claim 5, wherein each of the first, second, and third light emitting elements included in the red, green, and blue subpixels includes white light emitting elements in common and includes red, green, and blue color filters, respectively.

10. The display device according to claim 8, further comprising:
a white subpixel including a white light emitting element and a fourth driving transistor configured to drive the white light emitting element,
wherein the fourth driving transistor has a same S-factor value as one of the first, second, and third driving transistors.

11. A display device comprising:
a red subpixel including a red light emitting element and a first driving transistor for driving the red light emitting element;
a green subpixel including a green light emitting element and a second driving transistor for driving the green light emitting element; and
a blue subpixel including a blue light emitting element and a third driving transistor for driving the blue light emitting element,
wherein at least two of the red subpixel, the green subpixel, and the blue subpixel have different contact hole areas.

12. The display device according to claim 11, wherein each of the red, green, and blue subpixels have different ratios of a contact hole area to a same semiconductor layer area.

13. The display device according to claim 12, wherein the contact hole area includes an area of a contact hole overlapping the semiconductor layer in each of red, green, and blue subpixels.

14. The display device according to claim 13, wherein the contact hole area further includes an area of a contact hole disposed around the semiconductor layer in each of the red, green, and blue subpixels.

15. The display device according to claim 11, wherein the red subpixel has a first light emitting area,
the green subpixel has a second light emitting area larger than the first light emitting area, and
the blue subpixel has a third light emitting area larger than the second light emitting area.

16. The display device according to claim 15, wherein an efficiency of the green light emitting element is greater than an efficiency of the red light emitting element, and
the efficiency of the red light emitting element is greater than an efficiency of the blue light emitting element.

17. The display device according to claim 16, wherein the red subpixel has a first contact hole area,
the green subpixel has a second contact hole area smaller than the first contact hole area, and
the blue subpixel has a third contact hole area smaller than the second contact hole area.

18. The display device according to claim 16, wherein the first driving transistor has a first S-factor value,
the second driving transistor has a second S-factor value smaller than the first S-factor value, and
the third driving transistor has a third S-factor value smaller than the second S-factor value.

19. The display device according to claim 18, further comprising:
a white subpixel including a white light emitting element and a fourth driving transistor for driving the white light emitting element,
wherein the fourth driving transistor has a same S-factor value as one of the first, second, and third driving transistors.

20. The display device according to claim 12, wherein a ratio of the contact hole area to the semiconductor layer area in each of the red, green, and blue subpixels is in a range from 5% to 32%, inclusive.
